(19) United States
(12) Patent Application Publication
(10) Pub. No.: US 2017/0278897 A1
(43) Pub. Date: Sep. 28, 2017

(54) PACKAGE SUBSTRATE AND MANUFACTURING METHOD THEREOF, AND OLED DISPLAY DEVICE AND MANUFACTURING METHOD THEREOF

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Ning AO, Beijing (CN); Luopeng CHUO, Beijing (CN); Chonkyu MIN, Beijing (CN); Jin XU, Beijing (CN)

(73) Assignees: BOE Technology Group Co., Ltd., Beijing (CN); Ordos Yuansheng Optoelectronics Co., Ltd., Ordos, Inner Mongolia (CN)

(21) Appl. No.: 15/502,390

(22) PCT Filed: Aug. 17, 2016
(86) PCT No.: PCT/CN2016/095673

§ 371 Date: Feb. 7, 2017

(30) Foreign Application Priority Data
Nov. 4, 2015 (CN) 201510742598.6

(51) Int. Cl. H01L 27/32; H01S 5/42; H01L 33/64; G09G 3/3208; H01S 5/022

(52) U.S. Cl. CPC H01L 27/32; G09G 3/3208; H01S 5/02236; H01L 33/641; H01S 5/42

(57) ABSTRACT

A package substrate and a manufacturing method thereof, and an OLED display device and a manufacturing method thereof are provided. The package substrate comprises a base substrate (1), the base substrate (1) includes a bonding region (11) for coating an adhesive. The package substrate further comprises a first barrier wall (2) located on the base substrate (1), and the first barrier wall (2) is arranged along an outer side edge of the bonding region (11).

### TECHNICAL FIELD

Embodiments of the present disclosure relate to a package substrate and a manufacturing method thereof, and an OLED display device and a manufacturing method thereof.

### BACKGROUND

An Organic Light Emitting Diode (OLED) display device gradually becomes a main development tendency of a display device due to its advantages of self-illumination, high brightness, fast response speed, lightness and thinness, full color, no view angle difference and the like.

### SUMMARY

According to embodiments of the disclosure, a package substrate comprising a base substrate is provided. The base substrate includes a bonding region for coating an adhesive, the package substrate further comprises a first barrier wall located on the base substrate, and the first barrier wall is arranged along an outer side edge of the bonding region.

For example, a material of the first barrier wall is silicon oxide.

For example, a material of the first barrier wall is metal.

For example, an alignment mark is further arranged on the base substrate, and the alignment mark and the first barrier wall are formed by a same material.

For example, the first barrier wall is arranged along all of the outer side edge of the bonding region, so as to form a closed frame.

For example, a side of the first barrier wall close to the bonding region is perpendicular to the base substrate.

For example, a longitudinal section of the first barrier wall is in a shape of a rectangle.

For example, a height of the first barrier wall is less than a height of the adhesive coated in the bonding region.

For example, a height of the first barrier wall is 0.7 μm to 1.2 μm.

For example, the package substrate further comprises a second barrier wall arranged along an inner side edge of the bonding region.

According to the embodiments of the disclosure, a manufacturing method of a package substrate is provided. The method is for manufacturing the package substrate as described above. The manufacturing method of the package substrate comprises: providing a base substrate, the base substrate including a bonding region for coating an adhesive; and forming a first barrier wall on the base substrate along an outer side edge of the bonding region.

For example, an alignment mark is formed at the same time of forming the first barrier wall on the base substrate along the outer side edge of the bonding region, and the alignment mark is configured for aligning the package substrate and a display substrate upon bonding the package substrate and the display substrate.

According to the embodiments of the disclosure, an OLED display device is provided. The OLED display device comprises a display substrate and the above-described package substrate, and the package substrate and the display substrate are bonded with each other through the adhesive located in the bonding region.

According to the embodiments of the disclosure, a manufacturing method of an OLED display device is provided. The method is for manufacturing the above-described OLED display device. The manufacturing method of the OLED display device comprises: coating the adhesive along the inner side of the first barrier wall in the bonding region; covering the display substrate with the package substrate, so as to make the adhesive be in contact with the display substrate; and curing the adhesive.

### BRIEF DESCRIPTION OF THE DRAWINGS

FIG. 1 is a plan view I of a package substrate according to embodiments of the present disclosure;

FIG. 2 is a sectional view taken along an A-A′ direction in FIG. 1;

FIG. 3 is a sectional view after the package substrate is coated with an adhesive according to the embodiments of the present disclosure;

FIG. 4 is a plane view II of the package substrate according to the embodiments of the present disclosure;

FIG. 5 is a sectional view taken along an A-A′ direction in FIG. 4;

FIG. 6 is a flow chart illustrating a manufacturing method of a package substrate according to the embodiments of the present disclosure;

FIG. 7 is a sectional view of an OLED display device according to the embodiments of the present disclosure; and

FIG. 8 is a flow chart illustrating a manufacturing method an OLED display device according to the embodiments of the present disclosure.

### DETAILED DESCRIPTION

An OLED display device comprises a display substrate; and a cathode, an anode and an organic functional layer located between the cathode and the anode are arranged on the display substrate. The organic functional layer is very sensitive to water vapor and oxygen; and after contacting with the water vapor or the oxygen, the organic functional layer is oxidized very easily, which results in failure, and thus affects a display effect of the OLED display device. For example, the display substrate is packaged by a package substrate, so as to obstruct outside water vapor and outside oxygen and avoid failure of the organic functional layer. Specifically, the display substrate is packaged by the package substrate in a manner as follows: coating a glass sealant in a bonding region of the package substrate; covering the display substrate with the package substrate; performing laser radiation on the glass sealant, so as to cure the glass sealant and thus bond the package substrate and the display substrate.

However, inventors find that, because the glass sealant is sticky and easily flows; the glass sealant flows outwards after coating the package substrate with the glass sealant, which thus results in that burrs are generated on an edge of the glass sealant. In the case of performing the laser radiation on the glass sealant, laser only radiates the portion of the glass sealant located in the bonding region, such that the portion of the glass sealant in a region where the burrs are located cannot be cured and further a role of bonding the display substrate and the package substrate cannot be played, causing a waste of the glass sealant; meanwhile, a portion between adjacent burrs and on an outer side edge of the glass sealant can be easily invaded by the outside water vapor and the outside oxygen, and a service life of the OLED display device is seriously affected.

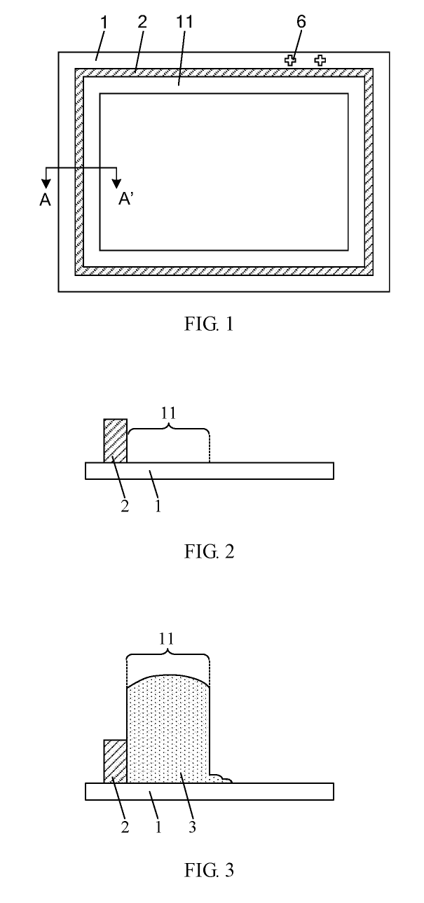

Embodiments of the present disclosure provide a package substrate. As shown in FIG. 1 and FIG. 2, the package substrate comprises a base substrate 1, the base substrate 1 includes a bonding region 11 for coating an adhesive, the package substrate further comprises a first barrier wall 2 located on the base substrate 1, and the first barrier wall 2 is arranged along an outer side edge of the bonding region 11, and the first barrier wall 2 is configured for obstructing outward flowing of the adhesive coated in the bonding region 11.

For example, the adhesive is a glass sealant.

After coating the adhesive on the package substrate of the above structure, as shown in FIG. 3, the first barrier wall 2 effectively obstructs outward flowing of the adhesive 3, so that an outer side edge of the adhesive 3 is aligned and has not any burrs, and therefore waste of the adhesive 3 is effectively avoided. An adhesive portion for forming burrs in the case that there is not the first barrier wall 2 is also located in the bonding region 11 in the case that the first barrier wall 2 is arranged, and therefore an amount of the adhesive 3 in the bonding region 11 is increased. Because of a squeezing effect of the first barrier wall 2 on the adhesive 3, a top of the adhesive 3 is in a shape of a gentle arc, therefore the top of the adhesive 3 makes more full contact with a display substrate, adhesion between the adhesive 3 and the display substrate is increased, and therefore a bonding effect of the adhesive 3 on the display substrate and the package substrate is improved. The first barrier wall 2 and the adhesive 3 jointly play a role of obstructing invasion of outside water vapor and outside oxygen, capacity of the OLED display device resisting invasion of the outside water vapor and the outside oxygen is improved, and a service life of the OLED display device is prolonged.

A material of the first barrier wall 2 is various, as long as outward flowing of the adhesive 3 coated in the bonding region 11 is obstructed. Exemplarily, the material of the first barrier wall 2 is silicon oxide (SiOx) or metal. Because a glass substrate generally serves as the base substrate 1 of the package substrate and the adhesive 3 generally includes glass powders and a bonding component, the first barrier wall 2 is well matched with the base substrate 1 and the adhesive 3 in the case that the material of the first barrier wall 2 is silicon oxide, so that the first barrier wall 2, the base substrate 1 and the adhesive 3 are stably connected. In addition, in the case that the material of the first barrier wall 2 is metal, the first barrier wall 2 is formed by a low cost wet etching without the use of high cost dry etching, which makes cost of the package substrate low. Furthermore, for example, an alignment mark 6 for aligning the package substrate with the display substrate upon bonding the package substrate and the display substrate is further arranged on the base substrate 1 of the package substrate. The first barrier wall 2 and the alignment mark 6 for example are formed by a single patterning process, which further reduces the cost of the package substrate. For example, the material of the first barrier wall 2 and a material of the alignment mark 6 are both molybdenum (Mo). For example, the alignment mark 6 is located on an outer side of the first barrier wall 2.

Position relationship between the first barrier wall 2 and the bonding region 11 is various. Exemplarily, the first barrier wall 2 is arranged along all of the outer side edge of the bonding region 11, or the first barrier wall 2 is arranged only along part of the outer side edge of the bonding region 11. As shown in FIG. 1, the first barrier wall 2 is arranged along all of the outer side edges of the bonding region 11 and forms a closed frame. That is to say, in the case of overlooking the package substrate, the first barrier wall 2 is in a shape of rectangle, so that the first barrier wall 2 surrounds the whole bonding region 11 of the base substrate 1 to obstruct outward flowing of the adhesive 3 coated in the whole bonding region 11, which further avoids waste of the adhesive 3, further improves the bonding effect of the adhesive 3 on the display substrate and the package substrate, further improves the capacity of the OLED display device resisting invasion of the outside water vapor and the outside oxygen, and further prolongs the service life of the OLED display device.

A longitudinal cross section (that is to say, a cross section taken along an A-A′ direction) of the first barrier wall 2 is in various shapes. In the case that a side of the first barrier wall 2 close to the bonding region 11 is perpendicular to the base substrate 1, an effect that the first barrier wall 2 avoids that the outer side edge of the adhesive 3 generates burrs is optimal. Exemplarily, the longitudinal cross section of the first barrier wall 2 is in a shape of a rectangle, or in a shape of L (bent in a direction away from the bonding region 11), or in a shape of a right trapezoid or the like. In the case that the longitudinal cross section of the first barrier wall 2 is in the shape of the rectangle, a structure of the first barrier wall 2 is simple, and a manufacturing process is simple. In the case that the longitudinal cross section of the first barrier wall 2 is in the shape of L or the right trapezoid, a contact area of the first barrier wall 2 and the base substrate 1 is great, which makes the first barrier wall 2 stably connected with the base substrate 1.

In addition, the inventors find that, in the case that a height of the first barrier wall 2 is too small, an obstructing effect on outward flowing of the adhesive 3 is not good; in the case that the height of the first barrier wall 2 is too great, it results in that the first barrier wall 2 touches the display substrate in a process of bonding the package substrate with the display substrate, and then a damage to the display substrate is caused. Thus, the height of the first barrier wall 2 needs to be reasonably set. For example, the height of the first barrier wall 2 is less than that of the adhesive 3. Exemplarily, the height of the first barrier wall 2 is 0.7 μm to 1.2 μm. After multiple factors of manufacturing cost of the first barrier wall 2, obstructing effect on outward flowing of the adhesive 3, whether the display substrate is damaged or not and the like are comprehensively considered, for example, the height of the first barrier wall 2 is 1 μm.

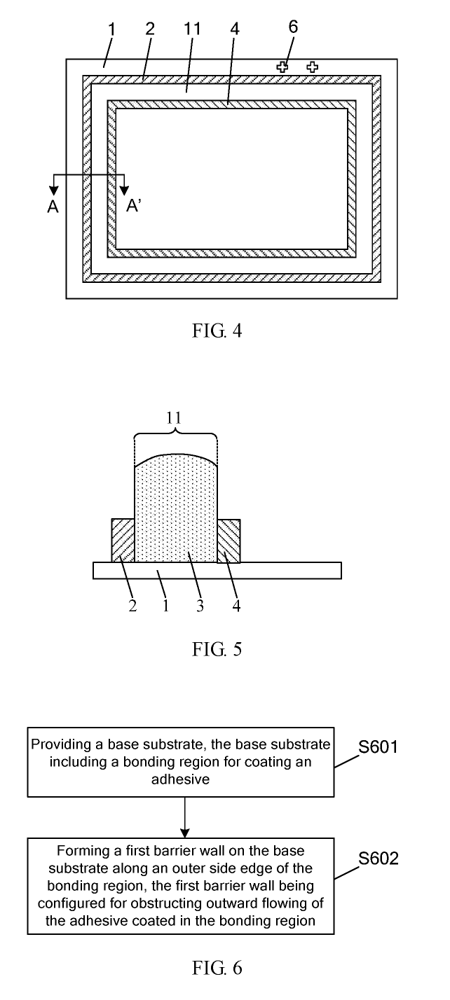

As shown in FIG. 4 and FIG. 5, the package substrate of the embodiments of the present disclosure further comprises a second barrier wall 4 arranged along an inner side edge of the bonding region 11, the second barrier wall 4 is configured for obstructing inward flowing of the adhesive 3 coated in the bonding region 11, which therefore avoids that the inner side edge of the adhesive 3 coated in the bonding region 11 generate burrs. After the adhesive 3 is cured (for example, the laser radiation is adopted for curing), no burrs exist on the inner side edge of the adhesive 3, waste of the adhesive 3 is further avoided, and the bonding effect of the adhesive 3 on the display substrate and the package substrate is further improved. A structure of the second barrier wall 4 is similar with that of the first barrier wall 2 and can refer to preceding description about the first barrier wall 2, which will not be repeated by the embodiments of the present disclosure.

The package substrate provided by the embodiments of the present disclosure has the structure as described above. Because the package substrate comprises the first barrier wall 2 arranged along the outer side edge of the bonding region 11 of the base substrate 1, the first barrier wall 2 effectively obstructs outward flowing of the adhesive 3 coated in the bonding region 11 upon coating the adhesive 3 on the package substrate, which therefore avoids that the outer side edge of the adhesive 3 generate burrs, avoids waste of the adhesive 3, and improves the bonding effect of the adhesive 3 on the display substrate and the package substrate; meanwhile, the first barrier wall 2 and the adhesive 3 jointly play the role of obstructing invasion of the outside water vapor and the outside oxygen, such that the capacity of the OLED display device resisting invasion of the outside water vapor and the outside oxygen is improved, and the service life of the OLED display device is prolonged.

The embodiments of the present disclosure further provide a manufacturing method of a package substrate, for manufacturing the package substrate described above. For example, as shown in FIG. 6, the manufacturing method of the package substrate comprises:

S601: providing a base substrate, the base substrate including a bonding region 11 for coating an adhesive 3.

S602: forming a first barrier wall 2 on the base substrate 1 along an outer side edge of the bonding region 11, the first barrier wall 2 being configured for obstructing outward flowing of the adhesive 3 coated in the bonding region 11.

It can be seen from the above description that, a material of the first barrier wall 2 is various. Thus, because materials of the first barrier wall 2 are different, manufacturing methods of the first barrier wall 2 are different.

Exemplarily, in the case that the material of the first barrier wall 2 is silicon oxide, the first barrier wall 2 is formed on the base substrate 1 along the outer side edge of the bonding region 11 in a following manner: firstly, forming a silicon oxide layer on the base substrate I by using for example a plasma enhanced chemical vapor deposition method; then, performing a patterning process on the silicon oxide layer to form a pattern including the first barrier wall 2, so as to form the first barrier wall 2 on the base substrate 1 along the outer side edge of the bonding region 11. For example, the patterning process comprises steps of coating photoresist, exposing with a mask having a corresponding pattern, developing, dry etching and stripping off the photoresist.

For example, the manufacturing method of the package substrate further comprises: forming an alignment mark 6 on the base substrate 1. For example, the alignment mark is configured for aligning the package substrate with a display substrate upon bonding the package substrate with the display substrate. Exemplarily, the step of forming the alignment mark on the base substrate 1 comprises: firstly, depositing a mask layer on the base substrate 1, and then performing a patterning process on the mask layer to form a pattern comprising the alignment mark. For example, the patterning process comprises steps of coating photoresist, exposing with a mask having a corresponding pattern, developing, wet etching and stripping off the photoresist.

Exemplarily, the first barrier wall 2 is formed on the base substrate 1 along the outer side edge of the bonding region 11 at the same time of forming the alignment mark, so as to simplify the manufacturing method of the package substrate and reduce cost of the package substrate. For example, the step of forming the first barrier wall 2 on the base substrate 1 along the outer side edge of the bonding region 11 at the same time of forming the alignment mark includes: depositing the mask layer on the base substrate 1, and performing a patterning process on the mask layer to form a pattern comprising the alignment mark and the first barrier wall 2. For example, the patterning process comprises steps of coating photoresist, exposing with a mask having a corresponding pattern, developing and wet etching and stripping off the photoresist. For example, the alignment mark and the first barrier wall 2 are formed by molybdenum.

What needs to be explained is that, the alignment mark may be formed after or before the first barrier wall 2 is formed.

What needs to be explained is that, the first barrier wall 2 may be formed on the base substrate 1 along the outer side edge of the bonding region 11 in other manners, which is not limited by the embodiments of the present disclosure. In addition, before forming various structures on the base substrate 1, cleaning the base substrate for example is performed.

For example, the manufacturing method of the package substrate further comprises: forming a second barrier wall 4 along an inner side edge of the bonding region 11. For example, a manufacturing process of the second barrier wall 4 is same as that of the first barrier wall 2, which will not be repeated herein. For example, in order to simplify a manufacturing process and reduce manufacturing cost of the package substrate, the first barrier wall 2 and the second barrier wall 4 are formed at the same time.

As mentioned above, the manufacturing method of the package substrate provided by the embodiments of the present disclosure comprises the step of forming the first barrier wall 2 on the base substrate 1 along the outer side edge of the bonding region 11, thus the first barrier wall 2 effectively obstructs outward flowing of the adhesive 3 coated in the bonding region 11 upon coating the adhesive 3 on the package substrate, which thus avoids that the outer side edge of the adhesive 3 generates burrs, avoids waste of the adhesive 3, and improves the bonding effect of the adhesive 3 on the display substrate and the package substrate; meanwhile, the first barrier wall 2 and the adhesive 3 jointly play the role of obstructing invasion of outside water vapor and outside oxygen, such that capacity of the OLED display device resisting invasion of the outside water vapor and the outside oxygen is improved, and the service life of the OLED display device is prolonged.

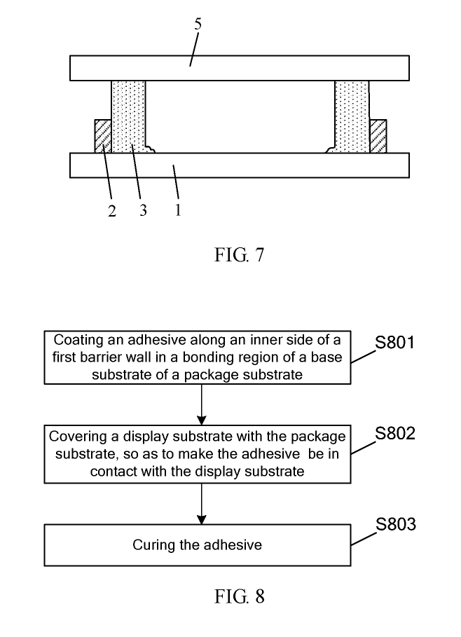

The embodiments of the present disclosure further provide an OLED display device, as shown in FIG. 7, the OLED display device comprises a display substrate 5 and the above-mentioned package substrate 1, and the package substrate 1 and the display substrate 5 are bonded through an adhesive 3 located in a bonding region 11. Because the above OLED display device comprises the above mentioned package substrate, no burrs exist on an outer side edge of the adhesive 3, waste of the adhesive 3 is avoided, and a bonding effect of the adhesive 3 on the display substrate 5 and the package substrate is improved; meanwhile, a first barrier wall 2 and the adhesive 3 jointly play a role of obstructing invasion of outside water vapor and outside oxygen, such that capacity of the OLED display device resisting invasion of the outside water vapor and the outside oxygen is improved, and a service life of the OLED display device is prolonged.

The embodiments of the present disclosure further provide a manufacturing method of the OLED display device, for manufacturing the above mentioned OLED display device. For example, as shown in FIG. 8, the manufacturing method of the OLED display device comprises: S801: coating an adhesive 3 along an inner side of a first barrier wall 2 in a bonding region 11 of a base substrate 1 of a package substrate. S802: covering a display substrate 5 with the package substrate, so as to make the adhesive 3 in contact with the display substrate 5. S803: curing the adhesive 3. Exemplarily, the adhesive 3 is cured in a laser radiation manner.

As mentioned above, the manufacturing method of the OLED display device provided by the embodiments of the present disclosure comprises the step of coating the adhesive 3 along the inner side of the first barrier wall 2, and therefore the first barrier wall 2 effectively obstructs outward flowing of the adhesive 3 coated in the bonding region 11, which thus avoids that an outer side edge of the adhesive 3 generates burrs, avoids waste of the adhesive 3, and improves a bonding effect of the adhesive 3 on the display substrate 5 and the package substrate; meanwhile, the first barrier wall 2 and the adhesive 3 jointly play a role of obstructing invasion of outside water vapor and outside oxygen, such that capacity of the OLED display device resisting invasion of the outside water vapor and the outside oxygen is improved, and a service life of the OLED display device is prolonged.

The foregoing embodiments merely are exemplary embodiments of the disclosure, and not intended to define the scope of the disclosure, and the scope of the disclosure is determined by the appended claims.

The present application claims priority of Chinese Patent Application No. 201510742598.6 filed on Nov. 4, 2015, the present disclosure of which is incorporated herein by reference in its entirety as part of the present application.

1. A package substrate, comprising a base substrate, wherein,
the base substrate includes a bonding region for coating an adhesive, the package substrate further comprises a first barrier wall located on the base substrate, and the first barrier wall is arranged along an outer side edge of the bonding region.

2. The package substrate according to claim 1, wherein, a material of the first barrier wall is silicon oxide.

3. The package substrate according to claim 1, wherein, a material of the first barrier wall is metal.

4. The package substrate according to claim 3, wherein, an alignment mark is further arranged on the base substrate, and the alignment mark and the first barrier wall are formed by a same material.

5. The package substrate according to claim 1, wherein, the first barrier wall is arranged along all of the outer side edge of the bonding region, so as to form a closed frame.

6. The package substrate according to claim 1, wherein, a side of the first barrier wall close to the bonding region is perpendicular to the base substrate.

7. The package substrate according to claim 6, wherein, a longitudinal section of the first barrier wall is in a shape of a rectangle.

8. The package substrate according to claim 1, wherein, a height of the first barrier wall is less than a height of the adhesive coated in the bonding region.

9. The package substrate according to claim 1, wherein, a height of the first barrier wall is 0.7 μm to 1.2 μm.

10. The package substrate according to claim 1, wherein, the package substrate further comprises a second barrier wall arranged along an inner side edge of the bonding region.)

11. A manufacturing method of a package substrate, comprising:
providing a base substrate, the base substrate including a bonding region for coating an adhesive; and
forming a first barrier wall on the base substrate along an outer side edge of the bonding region.

12. The manufacturing method of the package substrate according to claim 11, wherein, an alignment mark is formed at the same time of forming the first barrier wall on the base substrate along the outer side edge of the bonding region, and the alignment mark is configured for aligning the package substrate and a display substrate upon bonding the package substrate and the display substrate.

13. An OLED display device, comprising a display substrate and the package substrate according to claim 1, and the package substrate and the display substrate are bonded with each other through the adhesive located in the bonding region.

14. A manufacturing method of an OLED display device, for manufacturing the OLED display device according to claim 13, wherein,
the manufacturing method of the OLED display device comprises:
coating the adhesive along the inner side of the first barrier wall in the bonding region;
covering the display substrate with the package substrate, so as to make the adhesive be in contact with the display substrate; and
curing the adhesive.

15. The package substrate according to claim 4, wherein, the package substrate further comprises a second barrier wall arranged along an inner side edge of the bonding region.

16. The package substrate according to claim 15, wherein, the alignment mark, the first barrier wall and the second barrier wall are formed by the same material.

17. The package substrate according to claim 10, wherein, the second barrier wall arranged along all of the inner side edge of the bonding region.

18. The package substrate according to claim 10, wherein, a side of the second barrier wall close to the bonding region is perpendicular to the base substrate.

19. The package substrate according to claim 10, wherein, a longitudinal section of the second barrier wall is in a shape of a rectangle.

20. The package substrate according to claim 10, wherein, a height of the second barrier wall is less than a height of the adhesive coated in the bonding region.
